(19) United States
(12) Patent Application Publication
(10) Pub. No.: US 2026/0107653 A1
(43) Pub. Date: Apr. 16, 2026

(54) DISPLAY PANEL, METHOD OF MANUFACTURING DISPLAY PANEL

(71) Applicant: Hefei Visionox Technology Co., Ltd., Hefei (CN)

(72) Inventors: Xingfeng REN, Hefei (CN); Xuejing ZHU, Hefei (CN); Jui Yang TSAI, Hefei (CN)

(73) Assignee: Hefei Visionox Technology Co., Ltd., Hefei (CN)

(21) Appl. No.: 19/419,802

(22) Filed: Dec. 15, 2025

Related U.S. Application Data
(63) Continuation of application No. PCT/CN2025/131772, filed on Oct. 31, 2025.

(30) Foreign Application Priority Data
Sep. 25, 2025 (CN) 202511384756.5

(51) Int. Cl. H10K 59/131; H10K 59/12; H10K 59/122; H10K 59/80

(52) U.S. Cl. CPC H10K 59/131; H10K 59/1201; H10K 59/122; H10K 59/80515; H10K 59/8723

(57) ABSTRACT

A display panel and a method of manufacturing the display panel. The display panel includes a substrate, a conducting layer, an insulating layer and a light-emitting unit. The conducting layer includes a plurality of conducting traces spaced apart from one another. The insulating layer includes a first surface away from the substrate.

### CROSS REFERENCE TO RELATED APPLICATION

The present application is a continuation of International Application No. PCT/CN2025/131772, filed on Oct. 31, 2025, which claims priority to Chinese Patent Application No. 202511384756.5, filed on Sep. 25, 2025, titled with “DISPLAY PANEL, METHOD OF MANUFACTURING DISPLAY PANEL AND ELECTRONIC DEVICE”, both of which are hereby incorporated by reference in their entireties.

### FIELD

The present application relates to the field of display technology, and in particular to a display panel and a method of manufacturing a display panel.

### BACKGROUND

Organic light-emitting diodes (OLEDs) and flat display devices based on the light-emitting diode (LED) technology are widely used in various consumer electronics products such as mobile phones, televisions, laptops and desktop computers due to their advantages such as the high image quality, energy saving, thin body and wide application range, becoming the mainstream display panel. In the traditional display panel manufacturing process, a fine metal mask (FMM) is typically used to pattern light-emitting pixels. The FMM technology is mature and has the extensive mass production experience. However, the FMM technology also has problems such as the limited precision, high development cost and long development cycle. A fine metal mask-less technology eliminates the limitations of the traditional OLED processes on the display dimension, resolution and other screen performance aspects, and possesses the advantages such as the high performance, full-dimension display and agile delivery. Patents CN118251982A, CN115666161A, CN116648095A, CN117062489A, CN118678742A, CN118785761A, CN115224220A, CN118678729A, CN118660529A, and CN118660589A describe relevant content regarding the fine metal mask-less technology, and are provided for reference.

However, some problems still exist with the display panels that urgently need to be solved.

### SUMMARY

In order to overcome the problems mentioned in the background above, the present application provides a display panel includes:

a substrate;

a conducting layer, located on a side of the substrate, the conducting layer including a plurality of conducting traces spaced apart from one another;

an insulating layer located on a side of the conducting layer away from the substrate, the insulating layer including a first surface away from the substrate, and being provided with first through holes penetrating the insulating layer in a thickness direction of the substrate, each of the first through holes exposing a portion of a corresponding one of the conducting traces and including a sidewall and a first transition face arranged in the thickness direction of the substrate, and the first transition face connecting the sidewall with the first surface, and extending gradually away from a central axis of the first through hole in a direction away from the substrate; and

light-emitting units located on a side of the insulating layer away from the substrate, each of the light-emitting units including a first electrode, a light-emitting functional portion and a second electrode stacked in the direction away from the substrate, and at least a portion of the first electrode sequentially covering the first transition face and the sidewall, and being electrically connected to a corresponding one of the conducting traces.

In some possible embodiments, the present application further provides a display panel, the display panel includes:

a substrate;

a conducting layer, located on a side of the substrate, the conducting layer including a plurality of conducting traces spaced apart from one another;

an insulating layer located on a side of the conducting layer away from the substrate, the insulating layer including a first surface away from the substrate and being provided with first through holes penetrating the insulating layer in a thickness direction of the substrate, each of the first through holes exposing a portion of a corresponding one of the conducting traces and including a sidewall and a first transition face arranged in the thickness direction of the substrate, and the first transition face connecting the sidewall with the first surface; and light-emitting units located on a side of the insulating layer away from the substrate, each of the light-emitting units including a first electrode, a light-emitting functional portion and a second electrode stacked in a direction away from the substrate, and at least a portion of the first electrode sequentially covering the first transition face and the sidewall, and being electrically connected to a corresponding one of the conducting traces; and an included angle between the first transition face and the first surface being greater than 90°.

In some possible embodiments, the present application further provides a display panel, the display panel includes:

a substrate;

a conducting layer, located on a side of the substrate, the conducting layer including a plurality of conducting traces spaced apart from one another;

an insulating layer, located on a side of the conducting layer away from the substrate; the insulating layer including a first surface away from the substrate, and being provided with first through holes penetrating the insulating layer in a thickness direction of the substrate; each of the first through holes exposing a portion of a corresponding one of the conducting traces, and including a sidewall and a first transition face arranged in the thickness direction of the substrate; and the first transition face connecting the sidewall with the first surface, and gradually away from a central axis of the first through hole in a direction away from the substrate; and

light-emitting units, located on a side of the insulating layer away from the substrate, and each of the light-emitting units including a first electrode, a light-emitting functional portion and a second electrode stacked in a direction away from the substrate, and at least a portion of the first electrode sequentially covering the first transition face and the sidewall, and being electrically connected to a corresponding one of the conducting traces; and

a radius of curvature of the first transition face being different from a radius of curvature of the sidewall.

In some possible embodiments, the present application further provides a method of manufacturing a display panel, the method includes:

providing a substrate;

forming a conducting layer on a side of the substrate, the conducting layer including a plurality of conducting traces spaced apart from one another;

forming an insulating layer on a side of the conducting layer away from the substrate, the insulating layer including a first surface away from the substrate, and being provided with first through holes penetrating the insulating layer in a thickness direction of the substrate, each of the first through holes exposing a portion of a corresponding one of the conducting traces and including a sidewall and a first transition face arranged in the thickness direction of the substrate, and the first transition face connecting the sidewall with the first surface, and extending gradually away from a central axis of the first through holes in a direction away from the substrate; and forming light-emitting units on a side of the insulating layer away from the substrate, each of the light-emitting units including a first electrode, a light-emitting functional portion and a second electrode stacked in the direction away from the substrate, and at least a portion of the first electrode sequentially covering the first transition face and the sidewall, and being electrically connected to a corresponding one of the conducting traces.

The present application has the following beneficial effects:

the present application provides the display panel and the method of manufacturing the display panel; by arranging the first transition face on the side of the first through hole away from the substrate, it can make the first electrode smoother at the first transition face, thereby reducing the risk of the first electrode being damaged on the side of the first through hole away from the substrate, improving the display effect of the corresponding light-emitting unit, and ultimately improving the display effect of the display panel.

### BRIEF DESCRIPTION OF THE DRAWINGS

FIG. 1 is a cross-sectional schematic view of a first through hole of a display panel including a first transition face provided by an embodiment of the present application;

FIG. 2 is a cross-sectional schematic view of a first through hole of a display panel including a second transition face provided by an embodiment of the present application;

FIG. 3 is a cross-sectional schematic view of a display panel including a connecting portion and a filling portion provided by an embodiment of the present application;

FIG. 4 is another cross-sectional schematic view of the display panel including a connecting portion and a filling portion provided by an embodiment of the present application;

FIG. 5 is another cross-sectional schematic view of the display panel provided including a connecting portion and a filling portion by an embodiment of the present application;

FIG. 6 is a partial top view of a display panel provided by an embodiment of the present application;

FIG. 7 is a cross-sectional schematic view in line A-A in FIG. 6 provided by an embodiment of the present application;

FIG. 8 is another cross-sectional schematic view in line A-A in FIG. 6 provided by an embodiment of the present application;

FIG. 9A is a cross-sectional schematic view of a display panel including a encapsulation unit provided by an embodiment of the present application;

FIG. 9B is a cross-sectional schematic view of a encapsulation unit including a gap space provided by an embodiment of the present application;

FIG. 10A is a cross-sectional schematic view of a display panel including a second encapsulation layer and a third encapsulation layer provided by an embodiment of the present application;

FIG. 10B is another cross-sectional schematic view of a display panel including a second encapsulation layer and a third encapsulation layer provided by an embodiment of the present application;

FIG. 10C is another cross-sectional schematic view of a display panel including a second encapsulation layer and a third encapsulation layer provided by an embodiment of the present application;

FIG. 10D is another cross-sectional schematic view of a display panel including a second encapsulation layer and a third encapsulation layer provided by an embodiment of the present application;

FIG. 11 is a flowchart illustrating a method of manufacturing a display panel provided by an embodiment of the present application;

FIG. 12 is a cross-sectional schematic view of forming an insulating material layer on a side of a conducting layer away from a substrate provided by an embodiment of the present application;

FIG. 13 is a cross-sectional schematic view of forming a patterned photoresist layer on a side of the insulating material layer away from a substrate provided by an embodiment of the present application;

FIG. 14 is a cross-sectional schematic view of forming a first blind hole, which does not penetrate an insulating material layer, on the insulating material layer provided by an embodiment of the present application;

FIG. 15 is a cross-sectional schematic view of forming a third through hole at a second through hole by removing a portion of a patterned photoresist layer provided by an embodiment of the present application;

FIG. 16 is a cross-sectional view of forming an insulating layer provided by an embodiment of the present application;

FIG. 17 is a cross-sectional view of forming a connecting layer on a side of an insulating layer away from a substrate provided by an embodiment of the present application;

FIG. 18 is a cross-sectional view of forming a filling material layer on a side of a connecting layer away from a substrate provided by an embodiment of the present application;

FIG. 19 is a cross-sectional view of a patterned filling material layer provided by an embodiment of the present application;

FIG. 20 is a cross-sectional view of forming a first electrode on a side of a connecting portion and a filling portion away from a substrate provided by an embodiment of the present application;

FIG. 21 is a cross-sectional view of forming an isolation structure on a side of a connecting layer away from a substrate provided by an embodiment of the present application.

Reference numerals: 1. substrate; 2. conducting trace; 3. insulating layer; 31. first through hole; 311. sidewall; 312. first transition face; 313. second transition face; 314. first surface; 315. second surface; 4. pixel-defining layer; 41. pixel opening; 401. first sub-layer; 402. second sub-layer; 5. first electrode; 51. first electrode block; 511. first sub-electrode block; 512. second sub-electrode block; 513. third sub-electrode block; 6. light-emitting functional portion; 7. second electrode; 8. light-emitting unit; 9. connecting portion; 901, first groove; 91. first connecting sub-portion; 92. second connecting sub-portion; 10. filling portion; 11. isolation structure; 111. first isolation portion; 112. second isolation portion; 113. third isolation portion; 12. isolation opening; 13. encapsulation unit; 14. second encapsulation layer; 15. third encapsulation layer; 16. insulating material layer; 161. first blind hole; 17. patterned photoresist layer; 171. second through hole; 172. third through hole; 18. filling material layer; 19. conducting layer; 20. gap space.

### DETAILED DESCRIPTION

Increasing the density of light-emitting units (i.e., pixel density) in a display panel is a crucial way to improve the display quality. However, the density of the light-emitting units in the current display panel manufactured using the Fine Metal Mask (FMM) technology cannot increase due to the technological constraints. After long-term research by the inventor, it has been found that in order to solve the problem of the inability to further improve the density of light-emitting units, an isolation structure is provided in some display panels. When an entire layer of light-emitting layer and a second electrode are evaporated, the light-emitting layer and second electrode can be disconnected at the isolation structure. By performing multiple evaporation and etching processes (i.e., patterning the light-emitting units), the light-emitting units with different colors can be formed within different isolation openings.

The display panel in a related art includes a substrate, conducting traces located on a side of the substrate, an insulating layer on a side of the conducting traces away from the substrate, and light-emitting units one a side of the insulating layer away from the substrate. A first through hole, which penetrates the insulation layer, is provided on the insulation layer. The light-emitting unit includes a first electrode. The first electrode is electrically connected to the conducting traces through the first through hole. The conducting traces transmit the signal in a pixel circuit to the first electrode to cause the corresponding light-emitting unit emit light.

However, in the related art, a side of the first through hole away from the substrate is a right angle, i.e. an included angle between a sidewall of the first through hole and the side of the insulating layer away from the substrate is a right angle. Consequently, when the first electrode passes through the first through hole, it is easy for the first electrode to be damaged or even cut off by the right angle at the first through hole, which affects the light-emitting effect of the corresponding light-emitting unit and ultimately affects the display effect of the display panel.

In order to solve the aforementioned problems, the inventors have innovatively designed the following embodiments, which will be described in detail below with reference to the drawings. It should be noted that the defects in the solutions of the prior art described above are all results obtained by the inventors after practical experience and careful research. Therefore, the discovery process of the above-mentioned problems and the solutions proposed in the embodiments below should be considered contributions made by the inventors to the present application during the invention process, and should not be construed as technical content known to those skilled in the art.

Referring to FIG. 1, this embodiment provides a display panel including a substrate 1, a conducting layer 19, an insulating layer 3 and light-emitting units 8.

The conducting layer 19 is located on a side of the substrate 1 and includes a plurality of conducting traces 2 spaced apart from one another.

The display panel further includes a plurality of pixel circuits (not shown) located between the substrate 1 and the conducting layer 19. The conducting traces 2 are electrically connected to the pixel circuits, correspondingly.

The insulating layer 3 is located on a side of the conducting layer 19 away from the substrate 1. The insulating layer 3 includes a first surface 314 away from the substrate 1. In a thickness direction Z of the substrate 1, the insulating layer 3 is provided with first through holes 31 penetrating the insulating layer 3. The first through hole 31 exposes a portion of a corresponding one of the conducting traces 2. The first through hole 31 includes a sidewall 311 and a first transition face 312 arranged in the thickness direction of the substrate 1. The sidewall 311 is connected to the first surface 314 through the first transition face 312. In the direction Z away from the substrate, the first transition face 312 extends gradually away from a central axis of the first through hole 31.

The light-emitting unit 8 is located on a side of the insulating layer 3 away from the substrate 1. The light-emitting unit 8 includes a first electrode 5, a light-emitting functional portion 6 and a second electrode 7 stacked in the direction away from the substrate. At least a portion of the first electrode 5 sequentially covers the first transition face 312 and the sidewall 311, and is electrically connected to the corresponding one of the conducting traces 2.

The first electrode 5 is electrically connected to the conducting traces 2 through the first through hole 31. The relevant signals of the pixel circuits are transmitted to the first electrode 5 through the conducting traces 2. The first electrode 5 covers the first transition face 312. The first electrode 5 is gentler at the first transition face 312. The reaction force exerted by the first transition face 312 on the first electrode 5 is relatively small, thereby reducing the risk of damage to the first electrode 5 on the side of the first through hole 31 away from the substrate 1. This allows the relevant signals of the pixel circuit to be smoothly transmitted to the first electrode 5, thereby improving the display effect of the corresponding light-emitting unit 8 and addressing the issue of the dark spots in the corresponding light-emitting unit 8.

Based on the above design, this embodiment provides the first transition face 312 on the side of the first through hole 31 away from the substrate 1, which makes the first electrode 5 gentler at the first transition face 312, thereby reducing the risk of damage to the first electrode 5 on the side of the first through hole 31 away from the substrate 1, thereby improving the display effect of the corresponding light-emitting unit 8, and ultimately improving the display effect of the display panel.

In some possible embodiments, referring again to FIG. 1, an orthographic projection of the first transition face 312 on the substrate 1 is located within a range of an orthographic projection of the conducting trace 2 on the substrate 1. Thus, the dimension of the first through hole 31 can be reduced, and the positions of the first through hole 31 and the conducting trace 2 are more reasonable, and the pixel density of the display panel can increase.

In one embodiment, the orthographic projection of the first transition face 312 on the substrate 1 is arranged to circumferentially surround an orthographic projection of the sidewall 311 on the substrate 1. Thus, the first through hole 31 includes the first transition face 312 in each of different directions, thereby further reducing the risk of damage to the first electrode 5 on a side of the first through hole 31 away from the substrate 1.

In one embodiment, the maximum diameter of the orthographic projection of the first transition face 312 on the substrate 1 is shorter than the width of the conducting trace 2.

Herein a direction in which the conducting trace 2 extends is a length direction of the conducting trace 2, a direction perpendicular to the length direction of the conducting trace 2 is a width direction of the conducting trace 2, and the dimension of the conducting trace 2 in its width direction is the width of the conducting trace 2. Thus, the positions of the first through hole 31 and the conducting trace 2 can be arranged more reasonably, thereby improving the pixel density of the display panel.

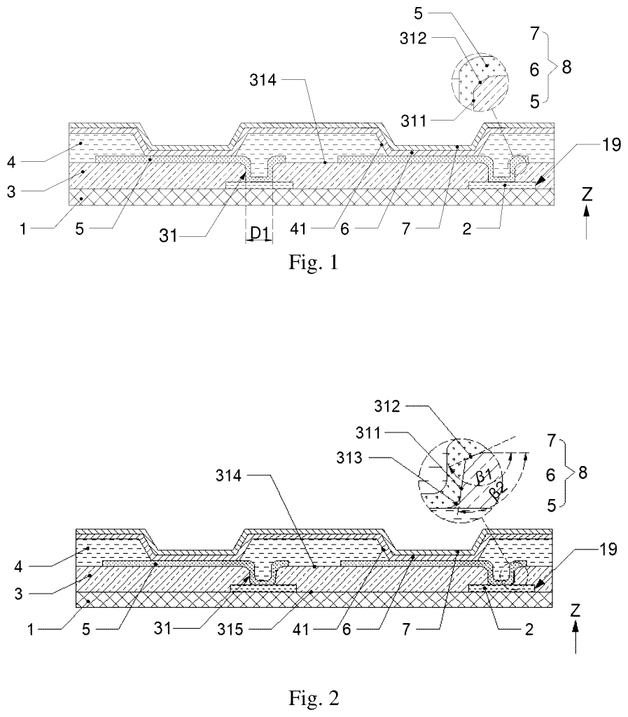

In one embodiment, referring to FIG. 2, the ratio of the dimension of the first transition face 312 in the thickness direction Z of the display panel to the width of the first transition face 312 in a plane where the substrate 1 is located is smaller than the ratio of the dimension of the sidewall 311 in the thickness direction Z of the display panel to the width of the sidewall 311 in the plane where the substrate 1 is located. Thus, the first transition face 312 is gentler than the sidewall 311, thereby further reducing the risk of damage to the first electrode 5 on the side of the first through hole 31 away from the substrate 1.

In one embodiment, the dimension of the first transition face 312 in the thickness direction Z of the display panel is smaller than the dimension of the sidewall 311 in the thickness direction Z of the display panel. Thus, the discontinuity of the first transition face 312 is smaller than that of the sidewall 311, thereby further reducing the risk of damage to the first electrode 5 on the side of the first through hole 31 away from the substrate 1.

In one embodiment, an included angle β1 between the first transition face 312 and the first surface 314 is greater than the included angle β2 between the sidewall 311 and the first surface 314.

Herein the included angle β1 between the first transition face 312 and the first surface 314 is an included angle between a tangent at some point on the first transition face 312 and the first surface 314. For example, in the cross-section of FIG. 2, the first transition face 312 is cut into an arc, and the first surface 314 is cut into a straight line. The included angle between a tangent at a point in the middle of the arc cut from the first transition face 312 and a straight line cut from the first surface 314 is served as the included angle β1 between the first transition face 312 and the first surface 314.

When the sidewall 311 is an inclined face, in the cross-section of FIG. 2, the sidewall 311 is cut into an inclined line. In this case, the included angle β2 between the sidewall 311 and the first surface 314 is the included angle between an extension line of the inclined line cut from the sidewall 311 in the direction away from the substrate 1 and a straight line cut from the first surface 314.

When the sidewall 311 is a curved face, in the cross-section of FIG. 2, the sidewall 311 is cut into an arc. In this case, the included angle β2 between the sidewall 311 and the first surface 314 is an included angle between the tangent at the point in the middle of the arc cut by the sidewall 311 and the straight line cut by the first surface 314.

Thus, the first transition face 312 is gentler than the sidewall 311, thereby further reducing the risk of damage to the first electrode 5 on the side of the first through hole 31 away from the substrate 1.

In some possible embodiments, referring to FIG. 2, the insulating layer 3 includes a second surface 315 close to the substrate 1. The sidewall 311 and the second surface 315 are connected by a second transition face 313. In a direction towards the substrate, the second transition face 313 gradually approaches a central axis of the first through hole 31. At least a portion of the first electrode 5 sequentially covers the first transition face 312, the sidewall 311, and the second transition face 313 and is electrically connected to the conducting trace 2.

The first electrode 5 is gentler at the second transition face 313, resulting in a gentler contact between the first electrode 5 and the conducting trace 2, thereby improving the electrical connection effect between the first electrode 5 and the conducting trace 2.

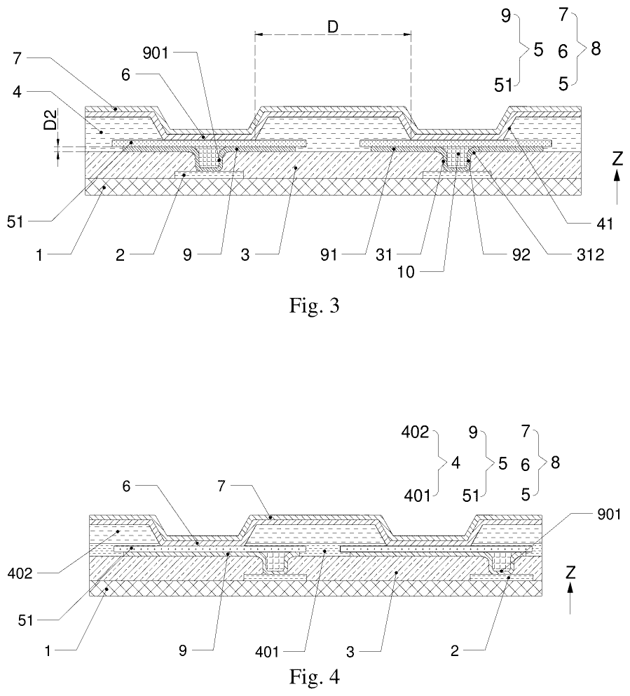

In some possible embodiments, referring to FIG. 3, the display panel further includes a pixel-defining layer 4 located on the side of the insulating layer 3 away from the substrate 1. The pixel-defining layer 4 encloses to define a plurality of pixel openings 41, at least a portion of the first electrode 5 is exposed through the pixel openings 41, and an orthographic projection of the first through hole 31 on the substrate 1 at least partially overlaps with an orthographic projection of the corresponding pixel opening 41 on the substrate 1.

In one embodiment, the orthographic projection of the first through hole 31 on the substrate 1 is located within a range of an orthographic projection of the pixel opening 41 on the substrate 1.

In this embodiment, the first through hole 31 is located on a side of the pixel opening 41 closest to the substrate 1. This solution can reduce a gap between the light-emitting units, thereby increasing the pixel density of the display panel.

In one embodiment, a central axis of the first through hole 31 overlaps with a central axis of the pixel opening 41. Thus, it not only further reduces the gap between the adjacent light-emitting units 8, increasing the pixel density of the display panel, but also ensures the symmetry of the first electrode 5, thereby facilitating the light emission of the light-emitting units 8 and improving the display effect of the display panel.

In other embodiments, referring to FIG. 4, the orthographic projection of the first through hole 31 on the substrate 1 and the orthographic projection of the corresponding pixel opening 41 on the substrate 1 are spaced apart from each other. That is, the orthographic projection of the first through hole 31 on the substrate 1 does not overlap with the orthographic projection of the corresponding pixel opening 41 on the substrate 1.

In this embodiment, the first through hole 31 is staggered with the pixel opening 41.

Both the two embodiments described above include the following solution: the first electrode 5 includes a connecting portion 9, which includes a first connecting sub-portion 91 and a second connecting sub-portion 92 connected to each other. The first connecting sub-portion 91 is located on the side of the insulating layer 3 away from the substrate 1. The second connecting sub-portion 92 covers the first transition face 312 and the sidewall 311, contacts the conducting trace 2, and forms a first groove 901.

In one embodiment, a filling portion 10 is provided in the first groove 901. The filling portion 10 can fill and level the first groove 901, thereby improving the flatness of the side of the first electrode 5 away from the substrate 1, and thus improving the light-emitting effect of the light-emitting unit 8.

In one embodiment, the first electrode 5 further includes a first electrode block 51, which is located on a side of the filling portion 10 away from the substrate 1, and extends to a side of the first connecting sub-portion 91 away from the substrate 1 to contact the first connecting sub-portion 91.

A filling portion 10 is located on a side of the connecting portion 9 away from the substrate 1 and fills the first groove 901. The first electrode block 51 is located on a side of the connecting portion 9 and the filling portion 10 away from the substrate 1, and the first electrode block 51 is electrically connected to the connecting portion 9.

In one embodiment, an orthographic projection of the filling portion 10 on the substrate 1 is located within an orthographic projection of the connecting portion 9 on the substrate 1.

In one embodiment, a side of the first electrode block 51 close to the substrate 1 is at least partially in contact with the side of the connecting portion 9 away from the substrate 1.

In one embodiment, the side of the first electrode block 51 close to the substrate 1 is in contact with the side of the filling portion 10 away from the substrate 1.

The connecting portion 9 covers the first transition face 312. The connecting portion 9 is gentler at the first transition face 312, and the reaction force of the first transition face 312 on the connecting portion 9 is smaller, which can reduce the risk of damage to the connecting portion 9 on the side of the first through hole 31 away from the substrate 1, improve the electrical connection effect between the connecting portion 9 and the conducting trace 2, and enable the relevant signals of the pixel circuit to be smoothly transmitted to the first electrode 5, thereby improving the display effect of the corresponding light-emitting unit 8 and mitigating the problem of dark spots in the corresponding light-emitting unit 8.

The connecting portion 9 is electrically connected to the first electrode block 51. Therefore, the signal from the conducting trace 2 can be transmitted to the first electrode block 51 through the connecting portion 9. The connecting portion 9 is typically recessed in a direction towards the substrate 1 at the first through hole 31. In this embodiment, since the filling part 10 partially fills the recessed portion of the connecting portion 9 at the first through hole 31, the first electrode block 51 can be flatter at the first through hole 31, thereby further improving the display effect of the display panel.

In one embodiment, in the thickness direction Z of the substrate 1, a thickness D2 of the connecting portion 9 is larger than or equal to 100 Å and less than or equal to 400 Å. For example, the thickness D2 can be 100 Å, 150 Å, 200 Å, 250 Å, 300 Å, 350 Å, or 400 Å, etc. By reasonably setting the thickness D2, the conducting trace 2 and the first electrode block 51 can be better electrically connected through the connecting portion 9 without excessively increasing the thickness of the display panel.

In one embodiment, in a direction parallel to the substrate 1, a maximum diameter of the first through hole 31 is less than a maximum diameter of the pixel opening 41.

In one embodiment, in the direction parallel to the substrate 1, the maximum diameter D1 of the first through hole 31 is larger than or equal to 1.5 μm and less than or equal to 3 μm. For example, the maximum diameter D1 can be 1.5 μm, 1.7 μm, 2 μm, 2.5 μm, 2.8 μm, or 3 μm, etc. By appropriately setting the maximum diameter D1, a spacing distance between two adjacent light-emitting units 8 can be reduced, thereby increasing the pixel density of the display panel.

In one embodiment, referring to FIG. 3 again, the distance D between the sides of two adjacent pixel openings 41 close to the substrate 1 is larger than or equal to 4.3 μm and less than or equal to 6 μm. For example, the distance D can be 4.3 μm, 4.5 μm, 5 μm, 5.5 μm, or 6 μm, etc. By appropriately setting the distance D, the spacing distance between two adjacent light-emitting units can be reduced, thereby increasing the pixel density of the display panel.

In an embodiment, referring to FIG. 4 again, the pixel-defining layer 4 includes a plurality of sub-layers, including a first sub-layer 401 and a second sub-layer 402 sequentially stacked in the direction away from the substrate 1; that is, the pixel-defining layer 4 can adopt a double-layer design.

Exemplarily, the film-forming property of the first sub-layer 401 is better than that of the second sub-layer 402. That is, under the same thickness conditions, the first sub-layer 401 can better cover the stepped structure formed by the first electrode compared to the second sub-layer 402, without causing cracks. Conversely, in order to achieve the same stepped coverage effect, the thickness of the first sub-layer 401 needs to be thinner than that of the second sub-layer 402, that is, the requirement for the thickness of the first sub-layer 401 is relatively low, which is beneficial for product thinning. Furthermore, the good film-forming property is reflected in the good coverage of the formed film, which is denser and more conducive to isolating the moisture.

Exemplarily, the second sub-layer 402 has a better etching resistance than the first sub-layer 401. Since a side of the pixel-defining layer 4 away from the substrate 1 will be etched during the display panel fabrication process, selecting a material with stronger etching resistance as the second sub-layer 402 can improve the etching resistance of the pixel-defining layer 4, further enhancing the reliability of the display panel.

Exemplarily, the materials of the first sub-layer 401 and the second sub-layer 402 are different. For example, the material of the first sub-layer 401 includes silicon nitride, and the material of the second sub-layer 402 includes silicon oxide.

In some possible embodiments, referring to FIG. 3 again, a distance between the side of the filling portion 10 away from the substrate 1 and the substrate 1 is equal to a distance between the side of the first connecting portion 91 away from the substrate 1 and the substrate 1.

In one embodiment, an orthographic projection of the first connecting portion 91 on the substrate 1 surrounds an orthographic projection of the second connecting portion 92 on the substrate 1.

In one embodiment, referring to FIG. 3 again, the side of the filling portion 10 away from the substrate 1 is a plane parallel to the substrate 1.

Thus, the filling portion 10 and the side of the first connecting portion 91 away from the substrate 1 are located on the same plane parallel to the substrate 1, which can further improve the flatness of the first electrode 5, thereby further improving the display effect and performance of the display panel.

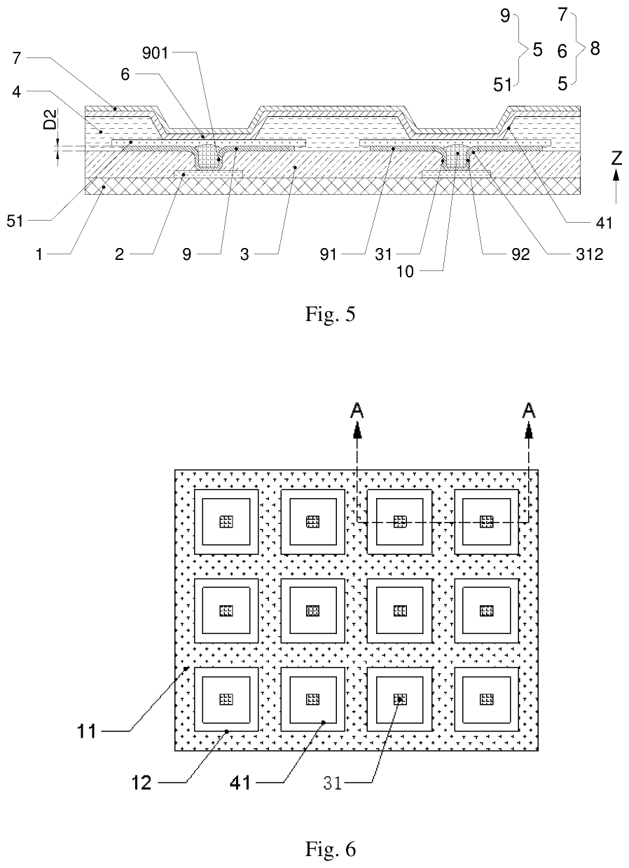

In one embodiment, referring to FIG. 5, in some embodiments, the side of the filling portion 10 away from the substrate 1 protrudes in the direction away from the substrate 1 and is in shape of arc. In one embodiment, the filling portion 10 can also be symmetrically arranged about the central axis of the first through hole 31, so as to ensure the symmetry of the first electrode block, thereby ensuring the display effect of the display panel.

In one embodiment, the material of the filling portion 10 is the same as the material of the insulating layer 3.

In one embodiment, the material of the filling portion 10 includes an organic material.

Both the filling portion 10 and the insulating layer 3 are made of the organic material, and the insulating layer 3 can be a planarization layer. Thus, it is easier to form the filling portion 10, and it is easier to make the side of the filling portion 10 away from the substrate 1 become a flat face.

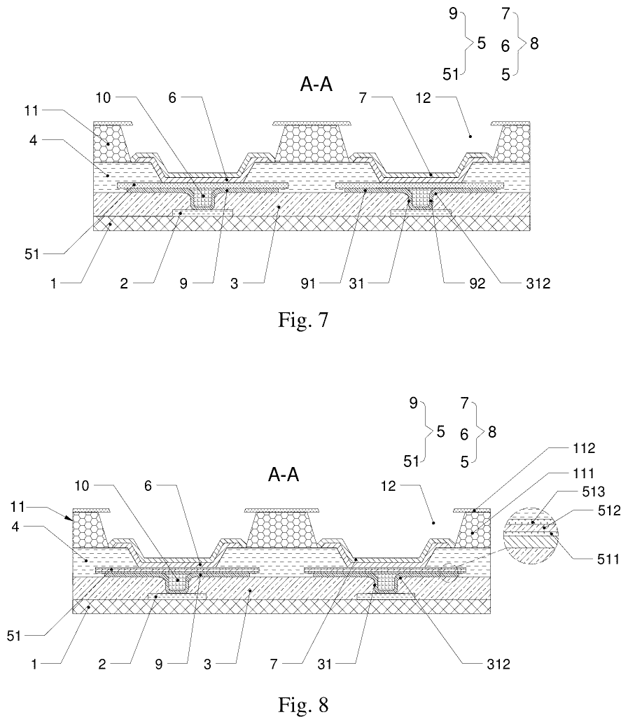

In some possible embodiments, as shown in FIG. 6 and FIG. 7, the display panel further includes an isolation structure 11 located on the side of the insulating layer 3 away from the substrate 1. The isolation structure 11 encloses to define a plurality of isolation openings 12. At least a portion of the light-emitting unit 8 is located within an isolation opening 12. The isolation structure 11 includes a conducting material, and the second electrode 7 is electrically connected to the isolation structure 11.

Based on the solutions in the above embodiments, the isolation structure 11 can be arranged, and the display panel with the isolation structure 11 has all the beneficial effects of the display panel in the above embodiments.

Arranging the isolation structure 11 allows the display panel to form film layers of different colors of light-emitting units 8 in different isolation openings 12 without the need for a fine mask. In one embodiment, when forming a light-emitting material layer, the light-emitting material layer can be separated by the isolation structure 11 to form a plurality of light-emitting functional portions 6 spaced apart from one another. When forming a second electrode material layer, the second electrode material layer can be separated by the isolation structure 11 to form a plurality of second electrodes 7 spaced apart from one another. The isolation structure 11 includes the conducting material, and the second electrodes 7 are electrically connected to the isolation structure 11. One first electrode 5, one light-emitting functional portion 6 and one second electrode 7 form one light-emitting unit 8. In this design, the first electrode 5 can be an anode, and the second electrode 7 can be a cathode.

Thus, different light-emitting units 8 can be independent with one another, thereby reducing the crosstalk between the adjacent light-emitting units 8 and improving the display effect of the display panel. Simultaneously, due to the presence of the isolation structure 11, both the light-emitting material layer and the second electrode material layer in the light-emitting unit 8 with each color in the display panel can be manufactured on the whole face and then patterned, so as to eliminate the fine mask and thus save on the manufacturing cost of the display panel.

In some possible embodiments, referring to FIG. 6 again, the orthographic projection of the first through hole 31 on the substrate 1 is located within an orthographic projection of the isolation opening 12 on the substrate 1.

In one embodiment, the orthographic projection of the first through hole 31 on the substrate 1 is located within the orthographic projection of the pixel opening 41 on the substrate 1.

In one embodiment, in the direction parallel to the substrate 1, the maximum diameter of the first through hole 31 is smaller than the maximum diameter of the isolation opening 12.

In one embodiment, the central axis of the first through hole 31 overlaps with a central axis of the isolation opening 12.

In the related art, if the first through hole 31 is formed on a side of the isolation structure 11 close to the substrate 1, it is not easy to reduce the spacing distance between adjacent light-emitting units 8, which is not conducive to forming the display panel with the high pixel density. If an orthogonal projection of the first through hole 31 on the substrate 1 is arranged to be located within an orthogonal projection of the pixel opening 41 on the substrate 1, the first electrode 5 may be recessed in the direction towards the substrate 1 at the first through hole 31, which can eventually cause the light-emitting functional portion 6 and the second electrode 7 and other film layers to also be recessed towards the substrate 1, thereby affecting the display effect and the reliability of the display panel.

In this embodiment, the connecting portion 9 is electrically connected to both the conducting trace 2 and the first electrode block 51. The filling portion 10 partially fills the recessed portion of the first electrode block 51 at the first through hole 31, and positions the first through hole 31 on the side of the pixel opening 41 close to the substrate 1. Thus, not only can it make the first electrode 5, the light-emitting functional portion 6, the second electrode 7 and other film layers flatter at the first through hole 31, but it is also more conducive to reducing the spacing distance between adjacent light-emitting units 8, thereby forming the display panel with higher pixel density.

In some possible embodiments, referring to FIG. 8, the first electrode block 51 includes a first sub-electrode block 511, a second sub-electrode block 512 and a third sub-electrode block 513 sequentially stacked in the direction away from the substrate 1. A side of the first sub-electrode block 511 facing the substrate 1 contacts the connecting portion 9 and the filling portion 10.

In one embodiment, the material of the first sub-electrode block 511 is the same as the material of the connecting portion 9.

In one embodiment, the material of the connecting portion 9 includes the indium tin oxide.

Generally, the adhesive effect between two film layers made of the same material is better than the adhesive effect between two film layers made of different materials. In this embodiment, the material of the first sub-electrode block 511 can be the same as that of the connecting portion 9, and a side of the first sub-electrode block 511 towards the substrate 1 is arranged to contact the connecting portion 9, so as to improve the adhesive force between the first sub-electrode block 511 and the connecting portion 9, and enhance the stability of the first electrode block 51.

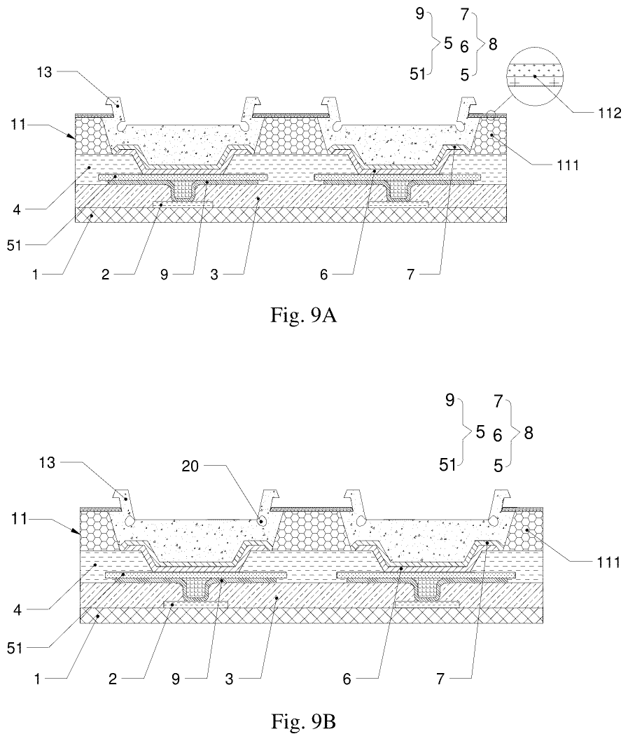

In some possible embodiments, referring to FIG. 9A, the display panel further includes a plurality of encapsulation units 13. The encapsulation unit 13 is located on a side of the corresponding light-emitting unit 8 away from the substrate 1, and a portion of the encapsulation units 13 extend from a side face of the isolation structure 11 towards the isolation opening 12 to a side of the isolation structure 11 away from the substrate 1.

In one embodiment, the plurality of encapsulation units 13 respectively corresponding to the plurality of light-emitting units 8 are spaced apart from one another.

In one embodiment, there is a gap between the encapsulation unit 13 located on the side of the isolation structure 11 away from the substrate 1 and the side of the isolation structure 11 away from the substrate 1.

During the process of patterning the light-emitting units 8, a first encapsulation material layer is broken at the isolation structure 11 to form the encapsulation unit 13. The encapsulation unit 13 can completely and independently encapsulate the corresponding light-emitting unit 8, thereby improving the display characteristics of the display panel.

Exemplarily, referring to FIG. 9B, the encapsulation unit 13 includes a first segment and a second segment connected to each other. The first segment is located within the isolation opening 12 and arranged on a side of the light-emitting unit 8 away from the substrate 1. The second segment is located on a side of the isolation structure 11 towards the isolation opening 12. A surface of the first segment away from the substrate 1 and a surface of the second segment away from the isolation structure 11 are at least partially connected to each other to enclose and form a gap space 20.

Exemplarily, referring again to FIG. 9A, alternatively, the surface of the first segment away from the substrate 1 and the surface of the second segment away from the isolation structure 11 may not be connected with each other.

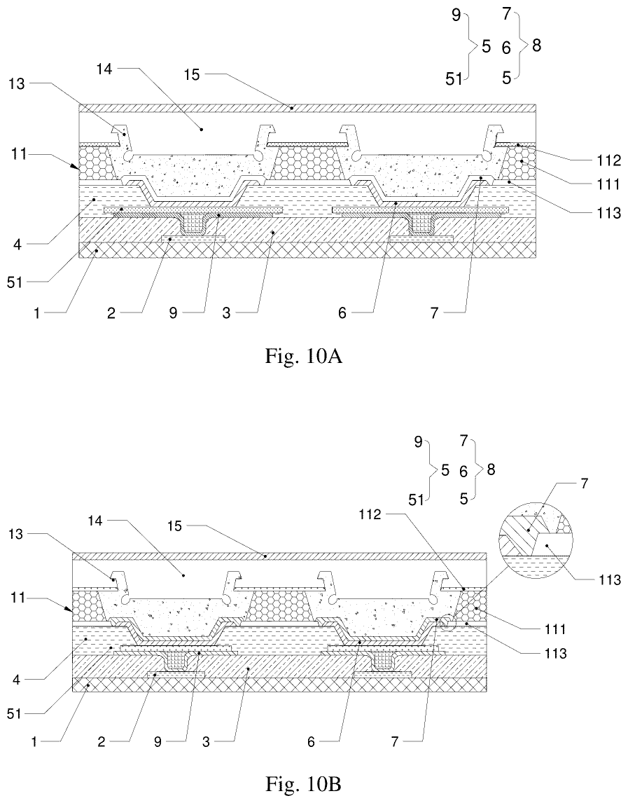

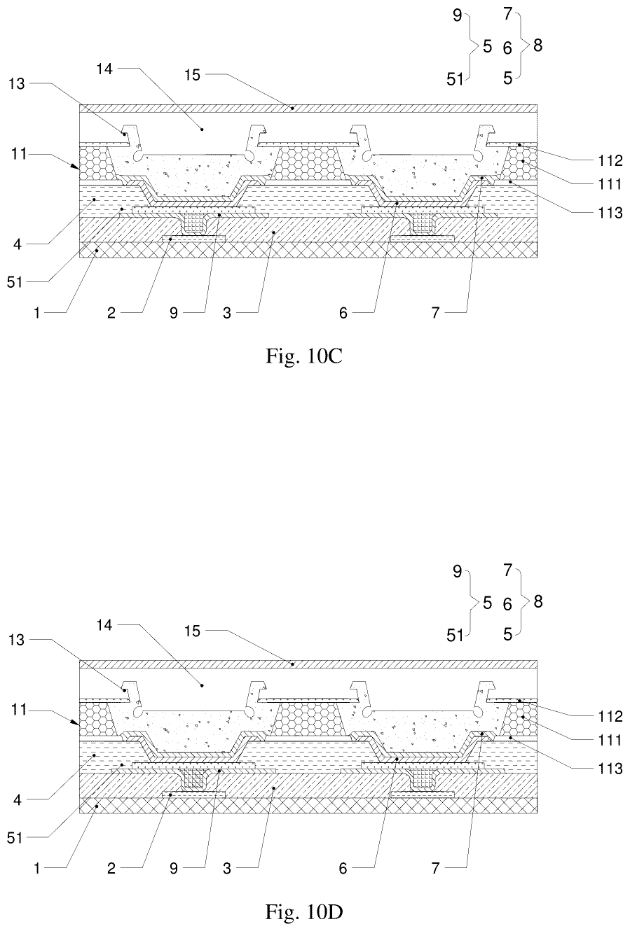

In some possible embodiments, referring to FIG. 10A, the display panel further includes a second encapsulation layer 14 located on a side of the encapsulation unit 13 away from the substrate 1 and a third encapsulation layer 15 located on a side of the second encapsulation layer 14 away from the substrate 1.

In one embodiment, each of the materials of the encapsulation unit 13 and the third encapsulation layer 15 includes the inorganic material, and the material of the second encapsulation layer 14 includes the organic material.

For example, the encapsulation unit 13 and the third encapsulation layer 15 can be formed by the chemical vapor deposition (CVD), and the second encapsulation layer 14 can be formed by the inkjet printing (IJP). The second encapsulation layer 14 and the third encapsulation layer 15 can achieve a better encapsulation effect on the light-emitting unit 8, thereby further improving the encapsulation quality of the display panel.

In some possible embodiments, referring to FIG. 8 again, the isolation structure 11 includes a first isolation portion 111 and a second isolation portion 112 sequentially stacked in the direction away from the substrate 1. An orthographic projection of a side of the first isolation portion 111 away from the substrate 1 on the substrate 1 is located within an orthographic projection of the second isolation portion 112 onto the substrate 1.

Since the second isolation portion 112 is located on the side of the first isolation portion 111 away from the substrate 1 and located in a plane parallel to the substrate 1, a lateral width of the second isolation portion 112 is larger than a lateral width of the first isolation portion 111. Therefore, the second isolation portion 112 causes the light-emitting material layer and the second electrode material layer to be disconnected at the isolation structure 11. Thus, due to the isolation structure 11 formed by the first isolation portion 111 and the second isolation portion 112, it can be easier to independently encapsulate each light-emitting unit 8, thereby improving the encapsulation yield of the display panel.

In one embodiment, referring to FIG. 8 again, the second electrode 7 of the light-emitting unit 8 is electrically connected to the first isolation portion 111; the first isolation portion 111 includes a conducting material, and the second electrode 7 corresponding to the light-emitting unit 8 extends to contact the sidewall 311 of the first isolation portion 111, so as to achieve the electrical connection between the second electrode 7 corresponding to the light-emitting unit 8 and the first isolation portion 111.

In one embodiment, referring to FIG. 8 again, the second isolation portion 112 can be a single-layer structure or a multi-layer structure. In the case that the second isolation portion 112 is a single-layer structure, the material of the second isolation portion 112 can include at least one of titanium, titanium nitride, molybdenum, tungsten, molybdenum-tungsten alloy or molybdenum-niobium alloy.

Referring to FIG. 9A, in the case that the second isolation portion 112 is the multi-layer structure, one layer of the second isolation portion 112 can be made of at least one of titanium, titanium nitride, molybdenum, tungsten, molybdenum-tungsten alloy or molybdenum-niobium alloy material. The other layer of the second isolation portion 112 can be made of a conducting oxide material, such as indium tin oxide (ITO) or indium zinc oxide (IZO), or an inorganic insulating material.

In one embodiment, referring to FIG. 10A again, the isolation structure 11 further includes a third isolation portion 113 located on a side of the first isolation portion 111 towards the substrate 1. The second electrode 7 of the light-emitting unit 8 is electrically connected to the third isolation portion 113.

In one embodiment, the first isolation portion 111 can be made of molybdenum or titanium; and/or the second isolation portion 112 can be made of aluminum, silver or copper; and/or the third isolation portion 113 can be made of titanium or molybdenum.

The third isolation portion 113 includes a conducting material and protrudes in a direction towards a center of the isolation opening 12 relative to the first isolation portion 111. The second electrode 7 corresponding to the light-emitting unit 8 extends to contact a side of the third isolation portion 113 away from the substrate 1, thereby achieving the electrical connection between the second electrode 7 corresponding to the light-emitting unit 8 and the third isolation portion 113.

In one embodiment, an orthographic projection of the light-emitting functional portion 6 on the substrate 1 is located out of an orthographic projection of the third isolation portion 113 on the substrate 1. Thus, the light-emitting functional portion 6 does not lap with the isolation structure 11, thereby effectively mitigating the crosstalk problem between the light-emitting units 8.

When the isolation structure 11 includes a three-layer structure including a first isolation portion 111, a second isolation portion 112 and a third isolation portion 113, the second electrode 7 can extend to a surface on a side of the third isolation portion 113 away from the substrate 1 to connect with the third isolation portion 113. In this case, the second electrode 7 may or may not be connected to the first isolation portion 111.

In some embodiments, referring to FIG. 10B, the second electrode 7 extends to the surface on the side of the third isolation portion 113 away from the substrate 1, and the second electrode 7 is not connected to the first isolation portion 111.

In other embodiments, referring to FIG. 10C, the second electrode 7 extends to the surface on the side of the third isolation portion 113 away from the substrate 1, and the second electrode 7 is connected to the first isolation portion 111.

In a first embodiment, referring to FIG. 10A again, the connecting portion 9 is recessed inwards relative to the first electrode block 51, and the pixel-defining layer 4 extends into a space of the connecting portion 9 recessed inwards relative to the first electrode block 51 and contacts a side of the connecting portion 9 away from the isolation opening 12. Thus, the area of the first electrode block 51 can increase without reducing the pixel density of the display panel, thereby improving the light-emitting effect of the light-emitting unit 8.

In the second embodiment, referring to FIG. 10B again, an orthographic projection of the first electrode block 51 on the substrate 1 is located within the orthographic projection of the connecting portion 9 on the substrate 1. The pixel-defining layer 4 covers the connecting portion 9 extending beyond the first electrode block 51, and an orthographic projection of the sidewall of the connecting portion 9 away from the center of the isolation opening 12 on the substrate 1 is located within an orthographic projection of the second isolation portion 112 on the substrate 1, and the orthographic projection of the sidewall of the connecting portion 9 away from the center of the isolation opening 12 on the substrate 1 is spaced apart from the orthographic projections of the first isolation portion 111 and the third isolation portion 113 on the substrate 1. Thus, since the connecting portion 9 extends beyond the first electrode block 51, the discontinuity of the pixel-defining layer 4 at a place between the connecting portion 9 and the sidewall of the first electrode block 51 is smaller, and the pixel-defining layer 4 can be not prone to breakage at the place between the connecting portion 9 and the sidewall of the first electrode block 51, and cannot affect the light-emitting effect of the light-emitting unit.

In the third embodiment, referring to FIG. 10C again, the orthographic projection of the first electrode block 51 on the substrate 1 is located within the orthographic projection of the connecting portion 9 on the substrate 1. The pixel-defining layer 4 covers the connecting portion 9 extending beyond the first electrode block 51. The orthographic projection of the sidewall of the connecting portion 9 away from the center of the isolation opening 12 on the substrate 1 is located within orthographic projections of the second isolation portion 112 and the third isolation portion 113 on the substrate 1. Furthermore, the orthographic projection of the sidewall of the connecting portion 9 away from the center of the isolation opening 12 on the substrate 1 is spaced apart from an orthographic projection of the first isolation portion 111 on the substrate 1. Thus, the length of the connecting portion 9 extending beyond the first electrode block 51 can increase, and the pixel-defining layer 4 can be less prone to breakage at the place between the connecting portion 9 and the sidewall of the first electrode block 51.

In the fourth embodiment, referring to FIG. 10D again, the orthographic projection of the first electrode block 51 on the substrate 1 is located within the orthographic projection of the connecting portion 9 on the substrate 1. The pixel-defining layer 4 covers the connecting portion 9 extending beyond the first electrode block 51. The orthographic projection of the sidewall of the connecting portion 9 away from the center of the isolation opening 12 on the substrate 1 is located within orthographic projections of the first isolation portion 111, the second isolation portion 112 and the third isolation portion 113 on the substrate 1. Thus, the length of the connecting portion 9 extending beyond the first electrode block 51 can increase, and the pixel-defining layer 4 can be less prone to breakage at the place between the connecting portion 9 and the sidewall of the first electrode block 51.

In some possible embodiments, referring to FIG. 2 again, this embodiment provides a display panel including a substrate 1, a conducting layer 19, an insulating layer 3, and a light-emitting unit 8.

The conducting layer 19 is located on a side of the substrate 1 and includes a plurality of conducting traces 2 spaced apart from one another.

The display panel further includes a plurality of pixel circuits (not shown) located between the substrate 1 and the conducting layer, and the conducting traces 2 are electrically connected to the pixel circuits, correspondingly.

The insulating layer 3 is located on a side of the conducting layer 19 away from the substrate 1. The insulating layer 3 includes a first surface 314 away from the substrate 1. In a thickness direction Z of the substrate 1, the insulating layer 3 is provided with a first through hole 31 penetrating the insulating layer 3. The first through hole 31 exposes a portion of the corresponding conducting trace 2. The first through hole 31 includes a sidewall 311 and a first transition face 312 arranged in the thickness direction of the substrate 1. The sidewall 311 is connected to the first surface 314 through the first transition face 312.

The light-emitting unit 8 is located on a side of the insulating layer 3 away from the substrate 1. The light-emitting unit 8 includes a first electrode 5, a light-emitting functional portion 6 and a second electrode 7 stacked in the direction away from the substrate. At least a portion of the first electrode 5 sequentially covers the first transition face 312 and the sidewall 311, and is electrically connected to the conducting traces 2.

An included angle β between the first transition face 312 and the first surface 314 is greater than 90°.

The first electrode 5 is electrically connected to the conducting traces 2 through the first through hole 31. The relevant signals of the pixel circuits are transmitted to the first electrode 5 through the conducting traces 2. Since the first electrode 5 covers the first transition face 312, and the included angle β between the first transition face 312 and the first surface 314 is greater than 90°, the first electrode 5 is gentler at the first transition face 312, and the reaction force exerted by the first transition face 312 on the first electrode 5 is relatively small, thereby reducing the risk of damage to the first electrode 5 on the side of the first through hole 31 away from the substrate 1. This allows the relevant signals of the pixel circuit to be smoothly transmitted to the first electrode 5, thereby improving the display effect of the corresponding light-emitting unit 8 and addressing the issue of the dark spots in the corresponding light-emitting unit 8.

The remaining embodiments of the display panel in this embodiment are the same as those in the above embodiments, and will not be repeated here.

In some possible embodiments, referring to FIG. 2 again, this embodiment provides a display panel including a substrate 1, a conducting layer 19, an insulating layer 3, and a light-emitting unit 8.

The conducting layer 19 is located on a side of the substrate 1 and includes a plurality of conducting traces 2 spaced apart from one another.

The display panel further includes a plurality of pixel circuits (not shown) located between the substrate 1 and the conducting layer 19. The conducting traces 2 are electrically connected to the pixel circuits, correspondingly.

The insulating layer 3 is located on a side of the conducting layer 19 away from the substrate 1. The insulating layer 3 includes a first surface 314 away from the substrate 1. In a thickness direction Z of the substrate 1, the insulating layer 3 is provided with a first through hole 31 penetrating the insulating layer 3. The first through hole 31 exposes a portion of the corresponding conducting trace 2. The first through hole 31 includes a sidewall 311 and a first transition face 312 arranged in the thickness direction of the substrate 1. The sidewall 311 is connected to the first surface 314 through the first transition face 312.

The light-emitting unit 8 is located on a side of the insulating layer 3 away from the substrate 1. The light-emitting unit 8 includes a first electrode 5, a light-emitting functional portion 6 and a second electrode 7 stacked in the direction away from the substrate. At least a portion of the first electrode 5 sequentially covers the first transition face 312 and the sidewall 311, and is electrically connected to the conducting traces 2.

A radius of curvature of the first transition face 312 is different from a radius of curvature of the sidewall 311.

The first electrode 5 is electrically connected to the conducting traces 2 through the first through hole 31. The relevant signals of the pixel circuits are transmitted to the first electrode 5 through the conducting traces 2. Since the first electrode 5 covers the first transition face 312, and the radius of curvature of the first transition face 312 is different from the radius of curvature of the sidewall 311, the first electrode 5 is gentler at the first transition face 312, and the reaction force exerted by the first transition face 312 on the first electrode 5 is relatively small, thereby reducing the risk of damage to the first electrode 5 on the side of the first through hole 31 away from the substrate 1. This allows the relevant signals of the pixel circuit to be smoothly transmitted to the first electrode 5, thereby improving the display effect of the corresponding light-emitting unit 8 and addressing the issue of the dark spots in the corresponding light-emitting unit 8.

In one embodiment, the radius of curvature of the first transition face 312 is smaller than the radius of curvature of the sidewall 311. Thus, the first transition face 312 is gentler, and the first electrode 5 is less prone to breakage at the first transition face 312.

The remaining embodiments of the display panel in this embodiment are the same as those in the above embodiments, and will not be repeated here.

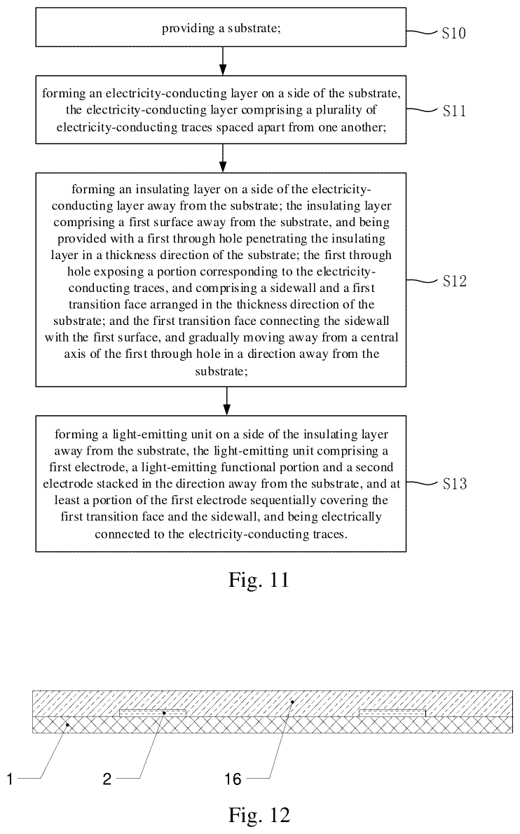

In some possible embodiments, referring to FIG. 1 and FIG. 11, the present application further provides a method of manufacturing a display panel, the method includes:

S10: providing a substrate 1.

S11: forming a conducting layer on a side of the substrate 1, and the conducting layer including a plurality of conducting traces 2 spaced apart from one another;

S12: forming an insulating layer 3 on a side of the conducting layer away from the substrate 1; the insulating layer 3 including a first surface 314 away from the substrate 1, and being provided with a first through hole 31 penetrating the insulating layer 3 in a thickness direction Z of the substrate 1; the first through hole 31 exposing a portion corresponding to the conducting traces 2, and including a sidewall 311 and a first transition face 312 arranged in the thickness direction of the substrate 1; and the first transition face 312 connecting the sidewall 311 with the first surface 314, and gradually moving away from a central axis of the first through hole 31 in the direction Z away from the substrate; and

S13: forming a light-emitting unit 8 on a side of the insulating layer 3 away from the substrate 1, the light-emitting unit 8 including a first electrode 5, a light-emitting functional portion 6 and a second electrode 7 stacked in the direction away from the substrate, and at least a portion of the first electrode 5 sequentially covering the first transition face 312 and the sidewall 311, and being electrically connected to the conducting traces 2.

In the display panel formed by the above method, the first electrode 5 is electrically connected to the conducting traces 2 through the first through hole 31. The relevant signals of the pixel circuits are transmitted to the first electrode 5 through the conducting traces 2. The first electrode 5 covers the first transition face 312. The first electrode 5 is gentler at the first transition face 312. The reaction force exerted by the first transition face 312 on the first electrode 5 is relatively small, thereby reducing the risk of damage to the first electrode 5 on the side of the first through hole 31 away from the substrate 1. This allows the relevant signals of the pixel circuit to be smoothly transmitted to the first electrode 5, thereby improving the display effect of the corresponding light-emitting unit 8 and addressing the issue of the dark spots in the corresponding light-emitting unit 8.

In some possible embodiments, the step of forming an insulating layer 3 on a side of the conducting layer away from the substrate 1 includes:

Referring to FIG. 12, forming an insulating material layer 16 on the side of the conducting layer away from the substrate 1.

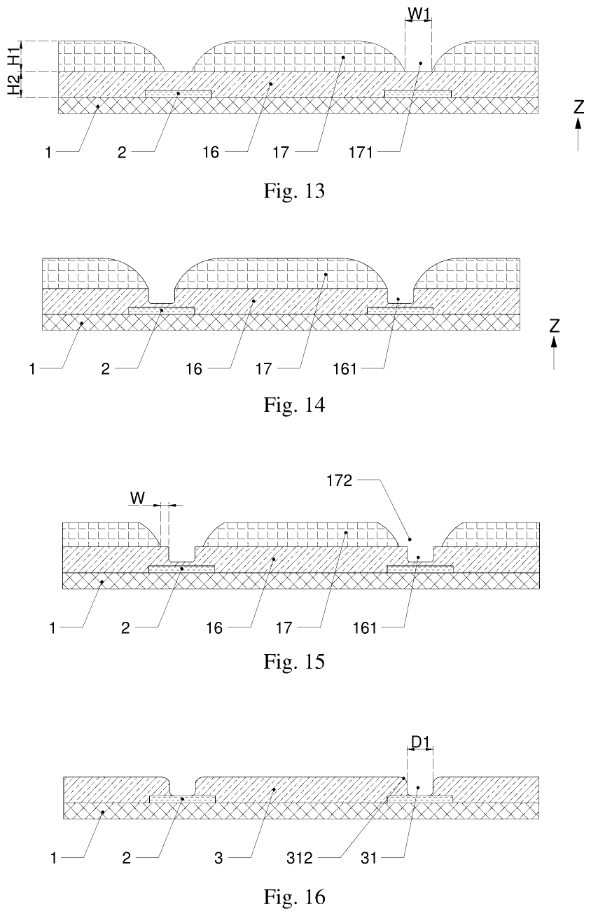

Referring to FIG. 13, forming a patterned photoresist layer 17 on a side of the insulating material layer 16 away from the substrate 1 using a phase-shift mask; the patterned photoresist layer 17 including a second through hole 171 in the thickness direction of the substrate 1, the second through hole 171 exposing a portion of the insulating material layer 16.

The patterned photoresist layer 17 can employ the high-resolution photoresist. Thus, in the case that the patterned photoresist layer 17 is in conjunction with the phase-shift mask, a smaller first through hole 31 can ultimately be formed on the insulating layer 3, thereby increasing the pixel density of the final formed display panel.

In one embodiment, in the thickness direction Z of the substrate 1, a ratio of a thickness H1 of the patterned photoresist layer 17 to a thickness H2 of the insulating material layer 16 is greater than or equal to 1.5 and less than or equal to 2. For example, the ratio of the thickness H1 to the thickness H2 can be 1.5, 1.6, 1.7, 1.8, 1.9, 2 or the like. By appropriately setting the ratio of the thickness H1 to the thickness H2, the area of the insulating material layer 16 exposed by the patterned photoresist layer 17 can be reduced, so as to reduce the dimension of the first through hole 31 formed on the insulating layer 3 in the direction parallel to the substrate 1, and thus facilitate forming the display panel with the high pixel density.

In one embodiment, in the direction parallel to the substrate 1, the dimension W1 of the second through hole 171 is larger than or equal to 1.3 μm and less than or equal to 2 μm.

By using the patterned photoresist layer 17 in conjunction with the phase-shifting mask, the dimension W1 of the second through hole 171 can be controlled to be larger than or equal to 1.3 μm and less than or equal to 2 μm. For example, the dimension W1 can be 1.3 μm, 1.4 μm, 1.5 μm, 1.6 μm, 1.7 μm, 1.8 μm, 1.9 μm, 2 μm or the like. By appropriately setting the dimension W1, the smaller first through hole 31 can ultimately be formed on the insulating layer 3, thereby increasing the pixel density of the final display panel.

Referring to FIG. 14, based on the patterned photoresist layer 17, in the thickness direction Z of the substrate 1, removing a portion of the insulating material layer 16 not covered by the patterned photoresist layer 17 to form a first blind hole 161 on the insulating material layer 16, and the first blind hole not penetrating the insulating material layer 16.

By using the relatively high longitudinal etching rate, the first blind hole 161 with a smaller dimension can be formed on the insulating material layer 16.

Referring to FIG. 15, removing a portion of the patterned photoresist layer 17, causing the second through hole 171 to form a third through hole 172, an orthogonal projection of the third through hole 172 on the substrate 1 covering an orthogonal projection of the second through hole 171 on the substrate 1, an orthogonal projection of the first blind hole 161 on the substrate 1 being located within the orthogonal projection of the third through hole 172 on the substrate 1, and the third through hole 172 exposing a portion of the insulating material layer 16.

By removing a portion of the patterned photoresist layer 17, the second through hole 171 retreats in a direction away from the first blind hole 161 to form the third through hole 172, so as to expose a portion of the insulating material layer 16.

Referring to FIG. 16, based on removing a portion of the patterned photoresist layer 17, removing the insulating material layer 16 between the first blind hole 161 and the conducting traces 2, and removing a portion of the insulating material layer 16 exposed by the third through hole 172 to form the insulating layer 3 including the first through hole 31.

Since the third through hole 172 exposes a portion of the insulating material layer 16, when the insulating material layer 16 between the conducting traces 2 and the first blind hole 161 is removed, a portion of the insulating material layer 16 exposed by the third through hole 172 will also be removed. While the insulating material layer 16 between the conducting trace 2 and the first blind hole 161 is removed, the third through hole 172 can further retreat in the direction away from the first blind hole 161, and the side of the first blind hole 161 away from the substrate 1 can be smoothed more gently, finally the first transition face 312 can be formed at this position, and the first blind hole 161 becomes the first through hole 31.

In one embodiment, the minimum distance W between the edges of the orthographic projections of the third through hole 172 and the first blind hole 161 on the substrate 1 is larger than or equal to 0.2 μm and less than or equal to 1 μm. For example, the minimum distance W can be 0.2 μm, 0.3 μm, 0.4 μm, 0.5 μm, 0.6 μm, 0.7 μm, 0.8 μm, 0.9 μm or 1 μm, etc. By appropriately setting the minimum distance W, the first through hole 31 with the smaller dimension can be formed, and the first transition face 312 can be formed on the side of the first through hole 31 away from the substrate 1.

In one embodiment, in the direction parallel to the substrate 1, a dimension D1 of an orthogonal projection of the first through hole 31 on the substrate 1 is larger than or equal to 1.5 μm and less than or equal to 3 μm. For example, the dimension D1 can be 1.5 μm, 1.7 μm, 2 μm, 2.5 μm, 2.8 μm or 3 μm, etc. By appropriately setting the dimension D1, the spacing distance between adjacent light-emitting units 8 can be reduced, thereby increasing the pixel density of the display panel.

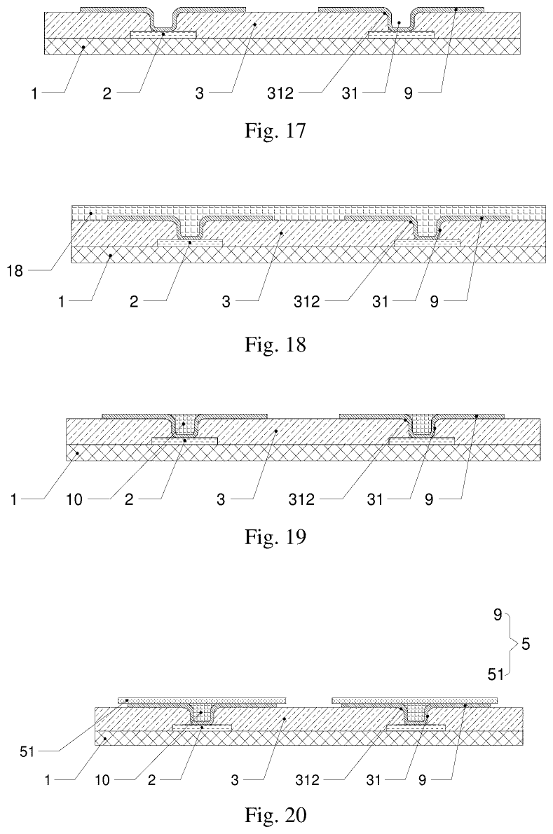

Referring to FIG. 17, forming a connecting material layer on the side of the insulating layer 3 away from the substrate 1, and patterning the connecting material layer to form a connecting layer, the connecting layer including a plurality of connecting portions 9 spaced apart from one another, and each of the connecting portions 9 extends from the side of the insulating layer 3 away from the substrate across the first transition face 312 and passes through the first through hole 31 to electrically connect with the corresponding one of the conducting traces 2.

The connecting portions 9 cover the first transition face 312, and are flatter at the first transition face 312. The reaction force exerted by the first transition face 312 on the connecting portion 9 is smaller, thereby reducing the risk of damage to the connecting portions 9 on the side of the first through hole 31 away from the substrate 1, and resulting in a better effect of the electrical connection between the connecting portions 9 and the conducting traces 2.

Referring to FIG. 18 and FIG. 19, forming a filling material layer 18 on a side of the connecting layer away from the substrate 1, and patterning the filling material layer 18 to form a filling layer, the filling layer including a plurality of filling portions 10 spaced apart from one another, the filling portions 10 being located on a side of the connecting portions 9 away from the substrate 1 and filling the first through hole 31.

The filling material layer 18 and the insulating layer 3 can be made of the same material, and both can be made of the organic material. Sides of the filling portions 10 and the connecting portions 9 away from the substrate 1 can be located on the same plane parallel to the substrate 1.

Referring to FIG. 20, forming a first electrode block 51 on a side of the connecting portions 9 and the filling portions 10 away from the substrate 1, and the first electrode block 51 being electrically connected to the connecting portions 9.

Since the sides of the filling portions 10 and the connecting portions 9 away from the substrate 1 are located on the same plane parallel to the substrate 1, the flatness of the first electrode 5 can be improved. Since the connecting portion 9 is not prone to damage at the first transition face 312 of the first through hole 31, the electrical connection between the first electrode block 51 and the conducting trace 2 can be improved, thereby allowing the relevant signals of the pixel circuits to be smoothly transmitted to the first electrode block 51.

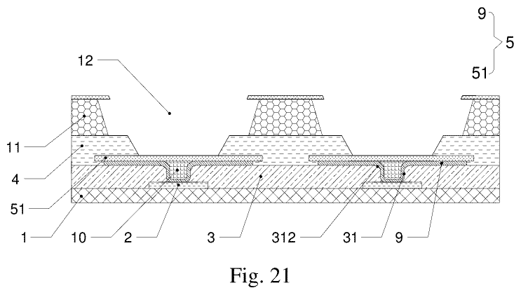

Referring to FIG. 21, forming an isolation structure 11 on the side of the connecting layer away from the substrate 1, and the isolation structure 11 enclosing to define a plurality of isolation openings 12.

Referring to FIG. 9 again, forming at least a portion of the light-emitting unit 8 within the isolation opening 12, and forming a pixel-defining layer 4 on the side of the light-emitting unit 8 away from the substrate 1.

In the display panel formed by the above method, since the first electrode block 51 is flatter at the first through hole 31 and the connecting portions 9 are not prone to damage at the first transition face 312, the display effect and the overall performance of the final formed display panel can be improved.

Furthermore, since the filling portion can fill and level the recessed position of the connecting portion at the first through hole, the first through hole can be formed on the side of the isolation opening close to the substrate, thereby reducing the distance between adjacent light-emitting units and increasing the pixel density of the display panel.

In some possible embodiments, the present application further provides an electronic device, which includes the display panel of the present application, or includes the display panel obtained by the method of manufacturing the display panel of the present application. The electronic device may include a device with the image processing capabilities, such as server, personal computer, laptop, mobile phone, tablet, wearable device, automotive display device and the like. Since the electronic device includes the display panel of the present application, the display effect of the electronic device can be significantly improved.

The technical features of the above embodiments can be combined in any way. For the sake of brevity, not all possible combinations of the technical features in the above embodiments are described. However, as long as there is no contradiction in the combination of these technical features, they should be considered to be within the scope of the description.

What is claimed is:

1. A display panel, comprising:
a substrate;
a conducting layer located on a side of the substrate, and the conducting layer comprising a plurality of conducting traces spaced apart from one another;
an insulating layer located on a side of the conducting layer away from the substrate, the insulating layer comprising a first surface away from the substrate, and being provided with first through holes penetrating the insulating layer in a thickness direction of the substrate, each of the first through holes exposing a portion of a corresponding one of the conducting traces and comprising a sidewall and a first transition face arranged in the thickness direction of the substrate, and the first transition face connecting the sidewall with the first surface, and extending gradually away from a central axis of the first through hole in a direction away from the substrate; and
light-emitting units located on a side of the insulating layer away from the substrate, each of the light-emitting units comprising a first electrode, a light-emitting functional portion and a second electrode stacked in the direction away from the substrate, and at least a portion of the first electrode sequentially covering the first transition face and the sidewall, and being electrically connected to a corresponding one of the conducting traces.

2. The display panel according to claim 1, wherein an orthographic projection of the first transition face on the substrate is located within a range of an orthographic projection of the corresponding one of the conducting traces on the substrate.

3. The display panel according to claim 2, wherein the orthographic projection of the first transition face on the substrate is arranged to circumferentially surround an orthographic projection of the sidewall on the substrate.

4. The display panel according to claim 2, wherein a maximum diameter of the orthographic projection of the first transition face on the substrate is shorter than a width of the corresponding one of the conducting traces.

5. The display panel according to claim 1, further comprising a pixel-defining layer located on the side of the insulating layer away from the substrate, wherein the pixel-defining layer encloses to define a plurality of pixel openings, at least a portion of the first electrode is exposed through a corresponding one of the plurality of pixel openings, and an orthographic projection of the first through hole on the substrate at least partially overlaps with an orthographic projection of a corresponding one of the plurality of pixel openings on the substrate.

6. The display panel according to claim 1, further comprising a pixel-defining layer located on the side of the insulating layer away from the substrate, wherein the pixel-defining layer encloses to define a plurality of pixel openings, at least a portion of the first electrode is exposed through a corresponding one of the plurality of pixel openings, and an orthographic projection of the first through hole on the substrate is spaced apart from an orthographic projection of the corresponding one of the plurality of pixel openings on the substrate.

7. The display panel according to claim 5, wherein the first electrode comprises a connecting portion, the connecting portion comprises a first connecting sub-portion and a second connecting sub-portion connected to each other, the first connecting sub-portion is located on the side of the insulating layer away from the substrate, and the second connecting sub-portion covers the first transition face and the sidewall, contacts the corresponding one of the conducting traces and forms a first groove.

8. The display panel according to claim 7, wherein a filling portion is provided in the first groove.

9. The display panel according to claim 8, wherein the first electrode further comprises a first electrode block, and the first electrode block is located on a side of the filling portion away from the substrate, extends to a side of the first connecting sub-portion away from the substrate, and contacts the first connecting sub-portion.

10. The display panel according to claim 1, further comprising a pixel-defining layer located on the side of the insulating layer away from the substrate, wherein the pixel-defining layer encloses to define a plurality of pixel openings, at least a portion of the first electrode is exposed through a corresponding one of the plurality of pixel openings, and a maximum diameter of the first through hole is smaller than a maximum diameter of a corresponding one of the plurality of pixel openings in a direction parallel to the substrate.

11. The display panel according to claim 1, wherein the insulating layer comprises a second surface close to the substrate, the side wall is connected to the second surface through a second transition face, and the second transition face gradually approaches the central axis of the first through hole in a direction towards the substrate; at least a portion of the first electrode sequentially covers the first transition face, the sidewall and the second transition face and is electrically connected to the corresponding one of the conducting traces.

12. The display panel according to claim 1, further comprising an isolation structure located on the side of the insulating layer away from the substrate, wherein the isolation structure encloses to define a plurality of isolation openings, at least a portion of each of the light-emitting units is located within a corresponding one of the plurality of isolation openings, the isolation structure comprises a conducting material, and the second electrode is electrically connected to the isolation structure; and
an orthographic projection of at least a portion of the first through hole on the substrate is located within an orthographic projection of a corresponding one of the plurality of isolation openings on the substrate.

13. The display panel according to claim 12, wherein the isolation structure comprises a first isolation portion and a second isolation portion sequentially stacked in the direction away from the substrate, and an orthographic projection of a side of the first isolation portion away from the substrate on the substrate is located within an orthographic projection of the second isolation portion on the substrate.

14. The display panel according to claim 13, wherein the first electrode comprises a connecting portion and a first electrode block at least partially stacked in the direction away from the substrate, the display panel further comprises a pixel-defining layer located between the insulating layer and the isolation structure, an orthographic projection of the first electrode block on the substrate is located within an orthographic projection of the connecting portion on the substrate, and the pixel-defining layer covers the connecting portion extending beyond the first electrode block.

15. A display panel, comprising:
a substrate;
a conducting layer located on a side of the substrate, the conducting layer comprising a plurality of conducting traces spaced apart from one another;
an insulating layer located on a side of the conducting layer away from the substrate, the insulating layer comprising a first surface away from the substrate and being provided with first through holes penetrating the insulating layer in a thickness direction of the substrate, each of the first through holes exposing a portion of a corresponding one of the conducting traces and comprising a sidewall and a first transition face arranged in the thickness direction of the substrate, and the first transition face connecting the sidewall with the first surface; and
light-emitting units located on a side of the insulating layer away from the substrate, each of the light-emitting units comprising a first electrode, a light-emitting functional portion and a second electrode stacked in a direction away from the substrate, and at least a portion of the first electrode sequentially covering the first transition face and the sidewall, and being electrically connected to a corresponding one of the conducting traces; and
an included angle between the first transition face and the first surface being greater than 90°.

16. The display panel according to claim 15, wherein an orthographic projection of the first transition face on the substrate is located within a range of an orthographic projection of a corresponding one of the conducting traces on the substrate.

17. The display panel according to claim 16, further comprising a pixel-defining layer located on the side of the insulating layer away from the substrate, wherein the pixel-defining layer encloses to define a plurality of pixel openings, at least a portion of the first electrode is exposed through a corresponding one of the plurality of pixel openings, and a maximum diameter of the first through hole is smaller than a maximum diameter of a corresponding one of the plurality of pixel openings in a direction parallel to the substrate.

18. A method of manufacturing a display panel, comprising:
providing a substrate;
forming a conducting layer on a side of the substrate, the conducting layer comprising a plurality of conducting traces spaced apart from one another;
forming an insulating layer on a side of the conducting layer away from the substrate, the insulating layer comprising a first surface away from the substrate, and being provided with first through holes penetrating the insulating layer in a thickness direction of the substrate, each of the first through holes exposing a portion of a corresponding one of the conducting traces and comprising a sidewall and a first transition face arranged in the thickness direction of the substrate, and the first transition face connecting the sidewall with the first surface, and extending gradually away from a central axis of the first through hole in a direction away from the substrate; and
forming light-emitting units on a side of the insulating layer away from the substrate, each of the light-emitting units comprising a first electrode, a light-emitting functional portion and a second electrode stacked in the direction away from the substrate, and at least a portion of the first electrode sequentially covering the first transition face and the sidewall, and being electrically connected to a corresponding one of the conducting traces.

19. The method of manufacturing a display panel according to claim 18, wherein the step of forming the insulating layer on the side of the conducting layer away from the substrate comprises:
forming an insulating material layer on the side of the conducting layer away from the substrate;
forming a patterned photoresist layer on a side of the insulating material layer away from the substrate, the patterned photoresist layer comprising second through holes in the thickness direction of the substrate, each of the second through holes exposing a portion of the insulating material layer;
based on the patterned photoresist layer, in the thickness direction of the substrate, removing a portion of the insulating material layer not covered by the patterned photoresist layer to form first blind holes on the insulating material layer, and the first blind holes not penetrate the insulating material layer;
removing a portion of the patterned photoresist layer, and causing the second through holes to form third through holes, an orthogonal projection of each of the third through holes on the substrate covering an orthogonal projection of a corresponding one of the second through holes on the substrate, an orthogonal projection of each of the first blind holes on the substrate being located within the orthogonal projection of a corresponding one of the third through holes on the substrate, and the third through holes exposing a portion of the insulating material layer; and
based on removing the portion of the patterned photoresist layer, removing the insulating material layer between the first blind holes and the conducting traces, and removing a portion of the insulating material layer exposed by the third through holes to form the insulating layer comprising the first through holes.

20. The method of manufacturing a display panel according to claim 18, wherein after the step of forming the insulating layer on the side of the conducting layer away from the substrate, the method further comprises:
forming a connecting material layer on the side of the insulating layer away from the substrate, and patterning the connecting material layer to form a connecting layer, the connecting layer comprising a plurality of connecting portions spaced apart from one another, and each of the connecting portions extending from the side of the insulating layer away from the substrate across the first transition face and passing through the first through hole to electrically connect with a corresponding one of the conducting traces;
forming a filling material layer on a side of the connecting layer away from the substrate, and patterning the filling material layer to form a filling layer, the filling layer comprising a plurality of filling portions spaced apart from one another, and the filling portions being located on a side of the connecting portions away from the substrate and filling the first through holes; and
forming a first electrode block on a side of the connecting portions and the filling portions away from the substrate, and the first electrode block being electrically connected to the connecting portions.
